(19) United States
(12) Patent Application Publication
(10) Pub. No.: US 2002/0195721 A1
(43) Pub. Date: Dec. 26, 2002

(54) Cavity down ball grid array packaging structure

(76) Inventors: Chun-Chi Lee, Kaohsiung (TW); Jaw-Shiun Hsieh, Kaohsiung (TW); Yao-Hsin Feng, Hualien (TW); Hou-Chang Kuo, Kaohsiung (TW); Kuan-Neng Liao, Kaohsiung (TW); Yu-Hsien Lin, Kaohsiung (TW)

Correspondence Address: J.C. Patents, Inc., Suite 250, 4 Venture, Irvine, CA, 92618, US

(21) Appl. No.: 10/091,945

(22) Filed: Mar. 5, 2002

(30) Foreign Application Priority Data
Jun. 21, 2001 (TW) 90115053

(51) Int. Cl. H01L 29/40; H01L 23/52; H01L 23/48

(52) U.S. Cl. 257/780

(57) ABSTRACT

In a cavity down BGA packaging structure, a circuit substrate is bonded onto a heat spreader. A cavity formed is formed in the circuit substrate into which a chip is bonded onto the heat spreader. The circuit substrate has at least an insulating layer, a patterned wiring layer, and a via electrically connected to the heat spreader. A first ground pad, ball pad, and first contact pad are defined on the patterned wiring layer, wherein the first ground pad is spaced apart from and electrically connected to the via. The chip comprises at least a second contact pad and a second ground pad respectively connected to the first contact pad and the heat spreader. An encapsulant material encapsulates the cavity, the chip, and the first and second contact pads. A plurality of solder balls are attached to the first ground pad and ball pad.

### CROSS-REFERENCE TO RELATED APPLICATION

This application claims the priority benefit of Taiwan application serial no. 90115053, filed Jun. 21, 2001.

### BACKGROUND OF THE INVENTION

1. Field of the Invention

The invention relates to a packaging structure. More particularly, the present invention relates to a packaging structure which uses a ball grid array connection structure.

2. Description of the Related Art

In integrated circuit (IC) packaging, ball grid array (BGA) connection structure provides several advantages such as high pin count and short electrical path. Conventionally, a BGA packaging structure comprises a BGA substrate onto which is bonded a chip. The contact pads of the chip are connected to the BGA substrate via conductive wires and an encapsulant material encapsulates the chip and the wires over the BGA substrate. Solder balls are conventionally attached to the BGA substrate to provide electrical connection to the external device. Because the BGA packaging structure such as the example described above favorably can receive a denser circuit layout, it is therefore commonly used in high density packaging structures.

As electronic devices are miniaturized, the density of devices on a chip substantially increases. When operating, the amount of heat per surface unit irradiated from the chip therefore significantly increases. Heat dissipation ability consequently is one critical factor in high-density packaging structures. With respect to BGA packaging structures, the cavity down BGA packaging structure is one specific structure designed to provide an improved heat dissipation.

Referring to FIG. 1, a cross-sectional view illustrates a conventional cavity down BGA packaging structure. The conventional cavity down BGA packaging structure 100 comprises a heat spreader 110. The heat spreader 110 has a chip-mounting region 112 and a substrate-mounting region 114 at the periphery of the chip-mounting region 112. The chip-mounting region 112 includes a cavity 116 into which is mounted the chip. An annular internal contact pad 120 and external contact pads 122 are selectively plated on a surface 118 of the substrate-mounting region 114, wherein the internal contact pad 120 is located around the cavity 116. A substrate 130 including at least an insulating layer 140 and a patterned wiring layer 150 is bonded onto the surface 118 of the substrate-mounting region 114, wherein a solder mask layer 160 further covers the top layer of the substrate 130. Ground pads 154, ball pads 156, and contact pads 158 are formed on the patterned wiring layer 150, and vias 170 pass through the insulating layer 140 and patterned wiring layer 150. More particularly, the vias 170 are formed such that they electrically connect the ground pads 154 by passing through the ground pads 154 at a central portion thereof.

A chip 200 having an active surface 202 and a corresponding back surface 204 is bonded via its back surface 204 onto the bottom surface of the cavity 216. The active surface 202 of the chip 200 further includes contact pads 206 and ground pads 208 respectively connected to the contact pads 158 and the internal contact pad 120 of the substrate 130 through wires (210, 220). An encapsulant material 180 encapsulates the cavity 116, chip 200, wires (210, 220), contact pads 158 and internal contact pad 120. Solder balls 190 are respectively attached onto the ground pads 154 and ball pads 156.

In the above-described packaging structure, the vias 170 are formed by screen printing a conductive material in via openings. The height of the thus formed vias 170 is not easily controlled and may substantially vary. As a result, the height of solder balls 190 subsequently formed on the ground pads 154 and ball pads 190 may not be uniform, which negatively affects the electrical connection of the packaging structure via the solder balls to the external device.

### SUMMARY OF THE INVENTION

An aspect of the present invention is to provide a cavity down ball grid array (BGA) packaging structure that can substantially ensure the height of the solder balls such that the reliability of the packaging structure and the process window are increased.

To attain at least the foregoing objectives, a cavity down BGA packaging structure comprises, according to an embodiment of the present invention, the following elements. Within the cavity down BGA packaging structure, a heat spreader includes a chip-mounting region arranged at a central region of the heat spreader, and a substrate-mounting region around the chip-mounting region. A circuit substrate is bonded to the heat spreader over the substrate-mounting region. The circuit substrate includes at least an insulating layer, a patterned wiring layer, and a via formed through the insulating layer and patterned wiring layer and connected to the heat spreader. The patterned wiring layer further includes at least a first ground pad, a ball pad, and a first contact pad. The via and the first ground pad of the patterned wiring layer are electrically connected to and sufficiently spaced apart from each other such that the heat spreader is connected to the first ground pad and a solder ball formed on the first ground pad does not contact the via. A chip having an active surface and a back surface is bonded to the heat spreader over the chip-mounting region through its back surface. The active surface of the chip includes at least a second contact pad and a second ground pad. The first and second contact pads are connected to each other and the second ground pad of the chip is connected to the heat spreader. An encapsulant material encapsulates the chip and first and second contact pads. A solder ball is formed on the ball pad.

In the cavity down BGA packaging structure of the present invention, the heat spreader can include, for example, a ground substrate bonded onto the heat spreader over the substrate-mounting region. The ground substrate then may have an opening that exposes the heat spreader underneath, thereby forming a cavity at the chip-mounting region where the chip is mounted in. In another example, the cavity of the chip-mounting region may be formed directly in the heat spreader. In still another example, the cavity may be formed in the circuit substrate bonded to the heat spreader over the substrate-mounting region.

In the cavity down BGA packaging structure of the present invention, the via is spaced apart from the first ground pad of the patterned wiring layer and can be electrically connected to the first ground pad by a ground conductive wiring. Alternatively, the via may contact the first ground pad at the periphery of the first ground pad.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view schematically illustrating a conventional cavity down BGA packaging structure;

FIG. 2 is a cross-sectional view schematically illustrating a cavity down BGA packaging structure according to an embodiment of the present invention;

FIG. 3 and FIG. 4 are enlarged top views illustrating various arrangements of the ground pad and via of FIG. 2 according to an embodiment of the present invention;

FIG. 5 and FIG. 6 are enlarged cross-sectional views illustrating the formation of the via of FIG. 2 according to an embodiment of the present invention;

FIG. 7 is a cross-sectional view illustrating a cavity down BGA structure according to a second embodiment of the present invention;

FIG. 8 is a cross-sectional view illustrating a cavity down BGA packaging structure according to a third embodiment of the present invention; and

FIG. 9 is a cross-sectional view illustrating the connection of a cavity down BGA packaging structure of the present invention to an external device.

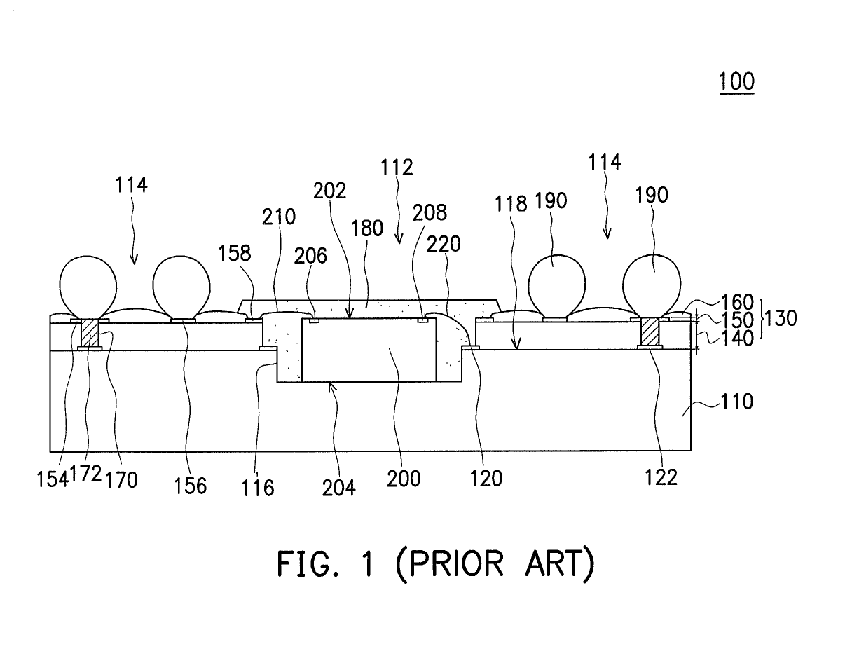

### DESCRIPTION OF THE PREFERRED EMBODIMENTS

The following detailed description of the embodiments and examples of the present invention with reference to the accompanying drawings is only illustrative of specific structures and ways of making of the present invention, and does not limit the scope of the present invention. In the description herein, the term “via” refers to the conventionally known hole structure in which is deposited a conductive material to connect different levels of devices.

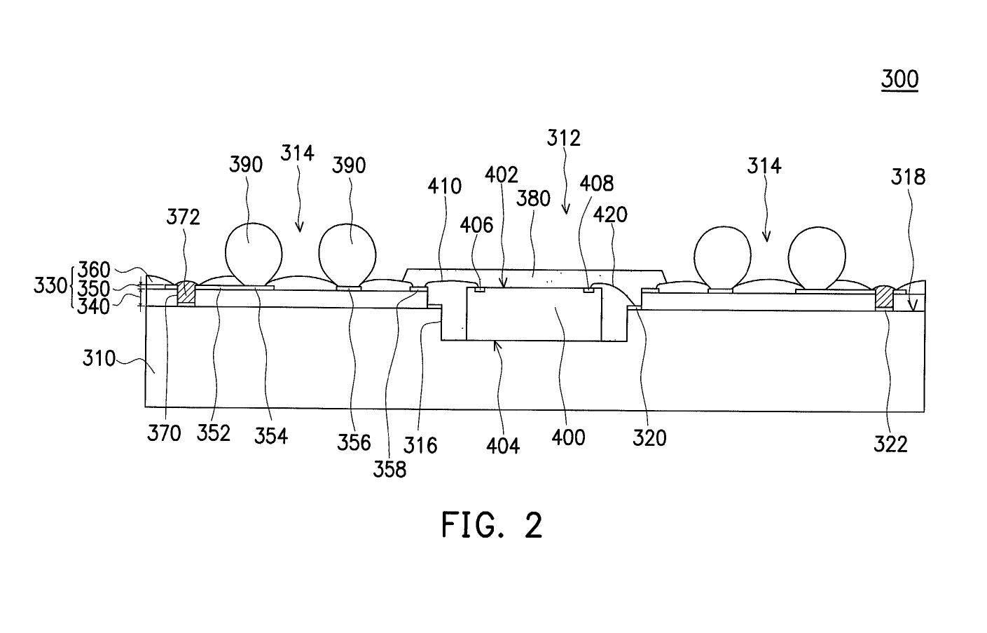

Referring now to FIG. 2, a cross-sectional view schematically illustrates a cavity down ball grid array (BGA) packaging structure according to an embodiment of the present invention. A cavity down BGA packaging structure 300 comprises a heat spreader 310. A chip-mounting region 312 and a substrate-mounting region 314 are defined on the heat spreader 310, wherein the substrate-mounting region 314 is located around the chip-mounting region 312. The chip-mounting region 312 can be formed, for example, in a central portion of the heat spreader 310. A cavity 316 is formed in the chip-mounting region 312. An internal contact pad 320 and a plurality of external contact pads 322 connected to one another are selectively plated on a surface 318 of the substrate-mounting region 314. The internal contact pad 320 may have an annular shape and may be arranged around the cavity 316, for example. The internal contact pad 320 and external contact pads 322 are made of metallic materials such as gold or silver, for example. Oxidization may be further performed to render the surface 318 of the substrate-mounting region 314 rough. The roughness of the surface 318 improves the subsequent bonding of a circuit substrate 330 on the substrate-mounting region 314.

The circuit substrate 330 includes at least an insulating layer 340 laminated with a patterned wiring layer 350, wherein a solder mask 360 further covers the top layer of the substrate 330 to protect the patterned wiring layer 350. A plurality of ground wirings 352, ground pads 354, ball pads 356, and contact pads 358 are defined on the patterned wiring layer 350. The circuit substrate 330 further includes a plurality of vias 370 formed through the insulating layer 340 and patterned wiring layer 350, and connected to the external contact pads 322. The ground wirings 352 electrically connect the vias 370, filled with a conductive material 372, to the ground pads 354 of the patterned wiring layer 350. The heat spreader 310 and circuit substrate 330 as described above form a chip carrier structure used in a cavity down BGA packaging structure of the present invention.

The cavity down BGA packaging structure 300 further includes a chip 400. The chip 400 has an active surface 402 and a back surface 404. The chip 400 is bonded onto the bottom surface of the cavity 316 via its back surface 404. A plurality of contact pads 406 and ground pads 408 formed on the active surface 402 of the chip 400 are respectively connected to the contact pads 358 and the internal contact pad 320 respectively by means of wires 410 and ground wires 420. An encapsulant material 380 encapsulates the cavity 316, chip 400, wires 410 and 420, contact pads 358 and internal contact pad 320. A plurality of solder balls 390 is respectively attached on the ground pads 354 and ball pads 356.

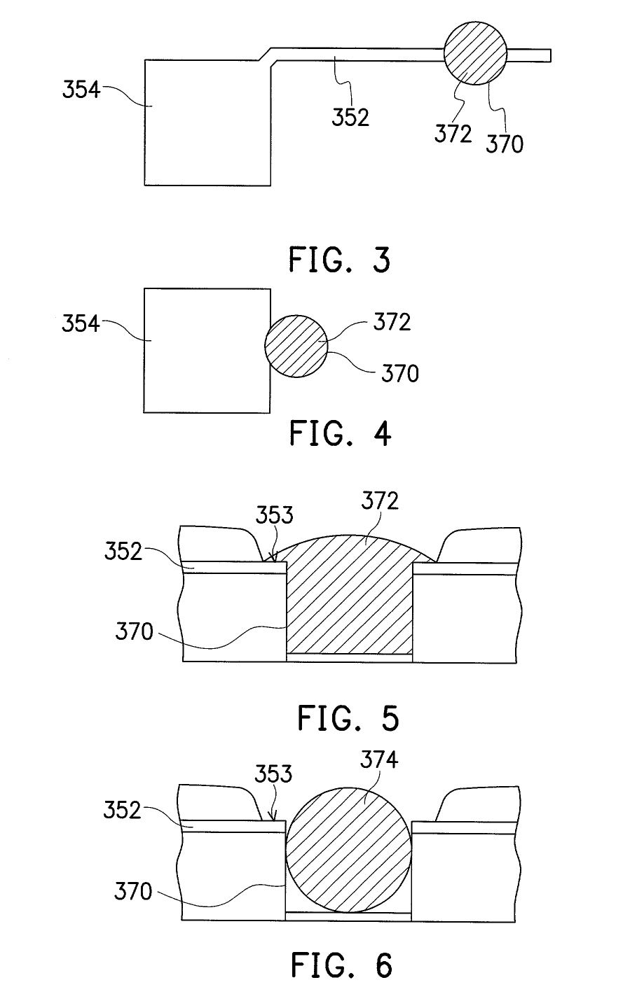

FIG. 3 is an enlarged top view that illustrates an example of arrangement of the ground pad and the via shown in FIG. 2 with greater detail. As shown in FIG. 3, the ground pad 354 is connected to the conductive material 372 of the via 370 by means of the ground wiring 352. Another alternative arrangement is shown in FIG. 4. In FIG. 4, the via 370 is located at the periphery of the ground pad 354 and is in direct electrical contact with the ground pad 354.

As described above, the ground pad 354 and the vias 370 are preferably spaced apart from each other in the packaging structure of the present invention. Solder balls 390 thus are not directly above the vias 370 as conventionally achieved. As a result, height difference between the solder balls 390 advantageously can be controlled within a reduced range, which consequently improves the process window of the subsequent processes.

Referring now to FIG. 5, an enlarged cross-sectional view schematically shows the via of FIG. 2. The conductive material 372 filling the via 370 overlaps onto the surface 353 of the ground wiring 352 connected to the via 370. By increasing the contact surface between the conductive material 372 and the ground wiring 352, the resulting electrical connection can therefore be improved. Via filling in the present invention can be accomplished by various methods known in the art. FIG. 6 illustrates an example of via filling performed in the present invention. A tin ball 374 first may be disposed in the via 370 opening, for example. Through a thermal process, the tin ball 374 then is reflowed to fill the via 370 opening with the conductive material 372, wherein the conductive material 372 overlaps over the ground wiring 352 as shown in FIG. 5.

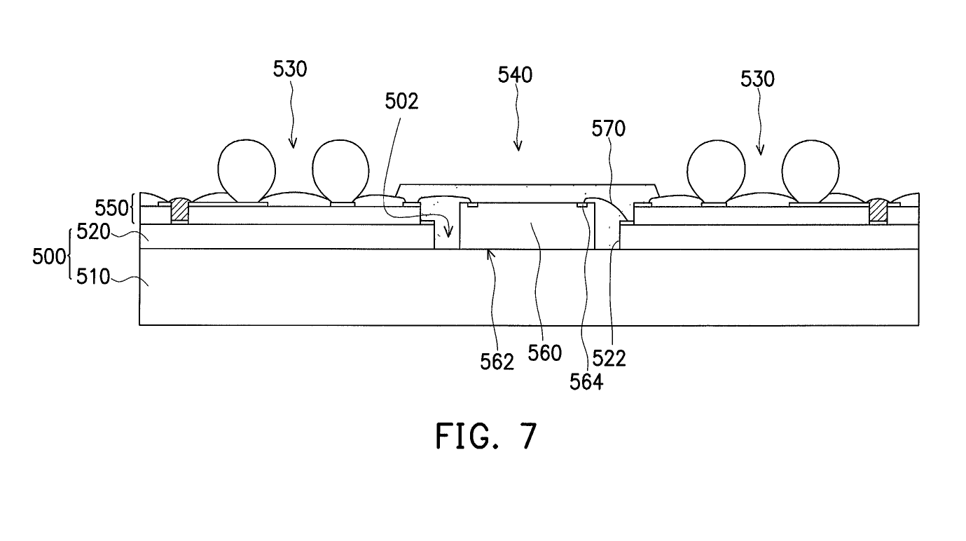

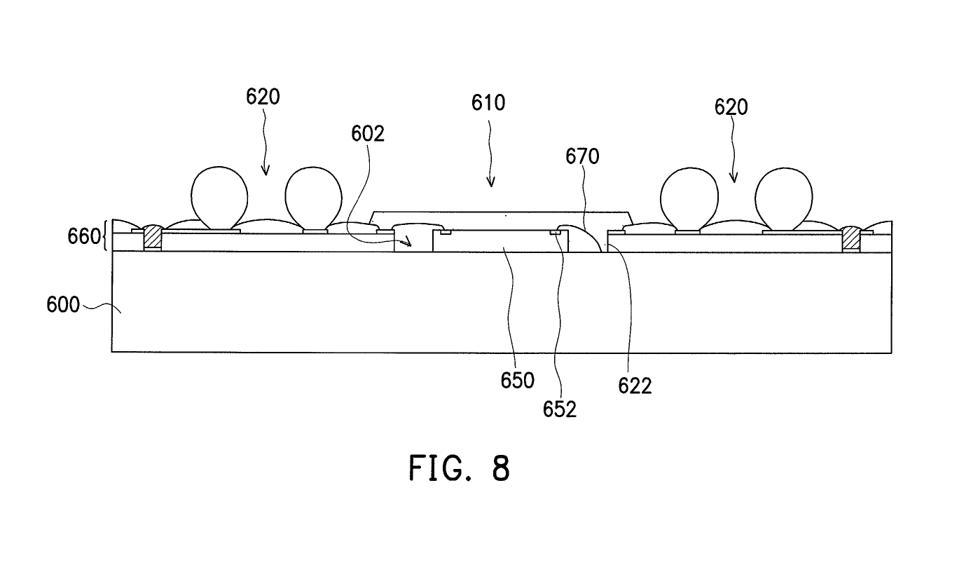

In the above-described cavity down BGA packaging structure of the present invention, the heat spreader 310 including the cavity 316 may be formed in one single body. FIG. 7 and FIG. 8 schematically show other cavity down BGA packaging structures alternative to the above structure.

Referring to FIG. 7, a cross-sectional view illustrates a cavity down BGA packaging structure according to a second embodiment of the present invention. In the present embodiment, a ground substrate 520 including an opening 522 is bonded onto the heat spreader 500. The opening 522 constitutes a cavity 502 that exposes the heat spreader 500 at a chip-mounting region 540 into which a chip 560, via its back surface 562, may be bonded onto the heat spreader 500. Similar to the previous embodiment, a circuit substrate 550 including at least an insulating layer, a patterned wiring layer, and a plurality of vias is further arranged over a substrate-mounting region 530 located around the chip-mounting region 540. A plurality of ground wires 570 connect the ground pads 564 of the chip 560 to the ground substrate 520.

Referring to FIG. 8, a cross-sectional view illustrates a cavity down BGA packaging structure according to a third embodiment of the present invention. In the present embodiment, a circuit substrate 660 including at least a patterned wiring layer is bonded onto the heat spreader 600 at a substrate-mounting region 620. An opening 662 directly formed in the circuit substrate 660 constitutes the cavity 602 of the chip-mounting region 610 in which the chip 650 is mounted. In the present embodiment, ground wires 670 connect the ground pads 652 of the chip 650 directly to the heat spreader 600.

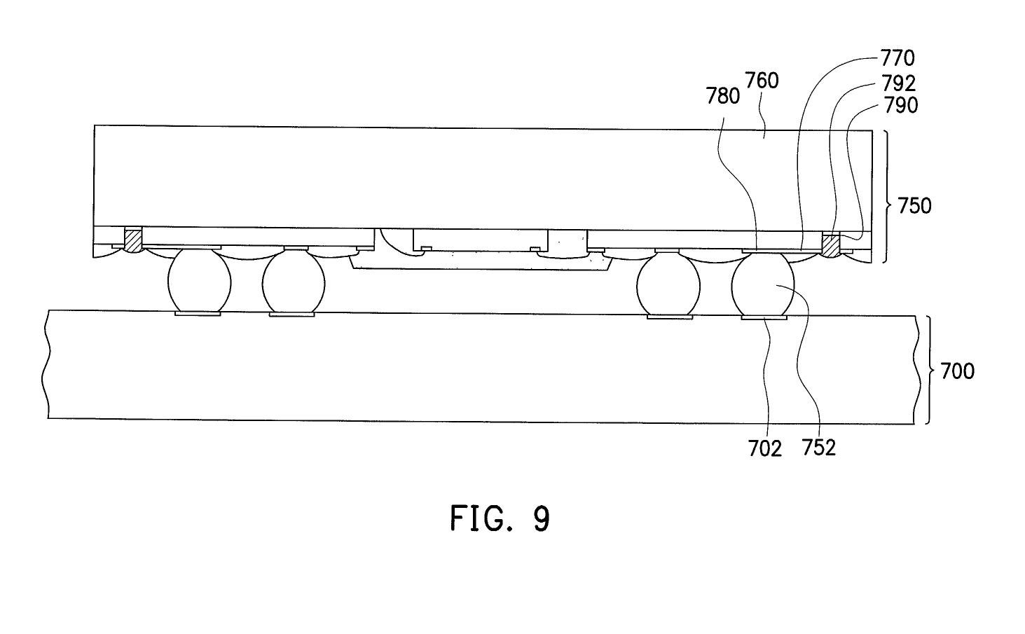

Referring now to FIG. 9, a cross-sectional view illustrates the connection of a cavity down BGA packaging structure of the present invention to an external device. The external device may be, for example, a printed circuit board 700 including a plurality of contact pads 702. A cavity down BGA packaging structure 750 of the present invention is connected to the printed circuit board 700 via a connection of solder balls 752 of the packaging structure 750 to the contact pads 702 of the printed circuit board 700. The cavity down BGA packaging structure 750 can be any of the previous embodiments disclosed in the present invention. Because the height difference between solder balls is reduced, reliability of the connection between the packaging structure of the present invention and the external device is therefore favorably improved.

In conclusion, at least one characteristic of the cavity down BGA package of the present invention is that the vias are spaced apart from the ground pads on the circuit substrate surface. Because the ground pads are not located on the vias as conventionally arranged, the ground pads are relatively more planar and conformal to the orientation of the circuit substrate surface. As a result, height difference between the solder balls formed on the ground pads can be controlled within a favorably reduced range, which improves the packaging structure external connection and the process window of the subsequent processing steps.

It will be apparent to those skilled in the art that various modifications and variations can be made to the structure and operations of the present invention without departing from the scope or spirit of the invention.

What is claimed is:

1. A cavity down ball grid array packaging structure, comprising:
a heat spreader including a chip-mounting region at a central portion and a substrate-mounting region located around the chip-mounting region;
a substrate bonded to the heat spreader in the substrate-mounting region, wherein the substrate comprises at least an insulating layer, a patterned wiring layer, and a via electrically connected to the heat spreader, and the patterned wiring layer comprises at least a ball pad, a first contact pad, and a first ground pad spaced apart from and electrically connected to the via;
a chip having an active surface and a corresponding back surface, the chip being bonded in the chip-mounting region of the heat spreader, wherein the active surface of the chip includes at least a second contact pad electrically connected to the first contact pad and a second ground pad electrically connected to the heat spreader;
an encapsulant material encapsulating the chip, the first and second contact pads; and
a plurality of solder balls attached to the ball pad and first ground pad.

2. The packaging structure of claim 1, wherein the heat spreader further includes a ground substrate bonded onto the substrate-mounting region, the ground substrate having an opening exposing the heat spreader at the chip-mounting region to form a cavity.

3. The packaging structure of claim 2, wherein the second ground pad of the chip is connected to the ground substrate on the heat spreader via a conductive wire.

4. The packaging structure of claim 1, wherein the heat spreader further includes a cavity therein at the chip-mounting region and the chip is mounted on a bottom surface of the cavity in the heat spreader.

5. The packaging structure of claim 4, wherein the second ground pad of the chip is connected to the heat spreader via a conductive wire.

6. The packaging structure of claim 1, wherein the first and second contact pads are connected to each other via a conductive wire.

7. The packaging structure of claim 1, wherein the via contacts with the first ground pad.

8. The packaging structure of claim 1, wherein the first ground pad is electrically connected to the via by means of a ground conductive wiring.

9. The packaging structure of claim 8, wherein the via is formed by disposing a conductive ball in a via opening and reflowing the conductive ball to form a conductive material filling the via opening and overlapping onto the ground conductive wiring.

10. A cavity down ball grid array packaging carrier, suitable for use in a chip packaging structure, the cavity down ball grid array carrier comprising:
a heat spreader including a chip-mounting region at a central portion and a substrate-mounting region located around the chip-mounting region; and
a substrate bonded to the heat spreader over the substrate-mounting region, wherein the substrate comprises at least an insulating layer, a patterned wiring layer, and a via connected to the heat spreader, and the patterned wiring layer comprises at least a ball pad, a contact pad, and a ground pad spaced apart from and electrically connected to the via.

11. The packaging carrier of claim 10, wherein the heat spreader further includes a ground substrate bonded onto the substrate-mounting region, the ground substrate having an opening exposing the heat spreader at the chip-mounting region to form a cavity.

12. The packaging carrier of claim 10, wherein the heat spreader further includes a cavity therein at the chip-mounting region and the chip is mounted on a bottom surface of the cavity in the heat spreader.

13. The packaging carrier of claim 10, wherein the via contacts the ground pad.

14. The packaging carrier of claim 10, wherein the patterned wiring layer further includes a ground conductive wiring connecting the via to the ground pad.
